(19) United States
(12) Patent Application Publication
(10) Pub. No.: US 2012/0107995 A1
(43) Pub. Date: May 3, 2012

(54) PROCESS FOR PRODUCING SOLAR CELL MODULE

(75) Inventors: Satoshi Niiyama, Tokyo (JP); Hiroshige Ito, Tokyo (JP); Mika Kambe, Tokyo (JP)

(73) Assignee: Asahi Glass Company, Limited, Tokyo (JP)

(21) Appl. No.: 13/313,561

(22) Filed: Dec. 7, 2011

Related U.S. Application Data
(63) Continuation of application No. PCT/JP2010/059637, filed on Jun. 7, 2010.

(30) Foreign Application Priority Data
Jun. 10, 2009 (JP) 2009-139426

(51) Int. Cl. H01L 31/18

(52) U.S. Cl. 438/64; 257/E31.117

(57) ABSTRACT

A process for producing a solar cell module, including (a) forming a seal part made of e.g. a double sided adhesive tape on the edge of a surface of a transparent surface material (first surface material), (b) supplying a liquid state photocurable resin composition to the region enclosed by the seal part, (c) laminating, in a reduced pressure atmosphere of not more than 100 Pa, on the photocurable resin composition, a glass substrate (second surface material) having a thin-film type solar cell device formed, to obtain a laminated material having the photocurable resin composition hermetically sealed, and (d) curing the photocurable resin composition in such a state that the laminated material is placed in a pressure atmosphere of not less than 50 kPa to form a resin layer.

### TECHNICAL FIELD

The present invention relates to a process for producing a solar cell module wherein a thin-film type solar cell device is protected by transparent surface materials.

### BACKGROUND ART

A solar cell module has a solar cell device sealed between a transparent front surface material to constitute a light-receiving surface and a back surface material by a sealing material such as a resin.

As the solar cell device, the following ones are known as generally classified.
A crystal type solar cell device formed from a silicon wafer (also called solar cell).
A thin-film type solar cell device formed by carrying out patterning sequentially every time when a transparent electrode layer, a photoelectric conversion layer and a backside electrode layer are, respectively, formed on the surface of a substrate.
A thin-film type solar cell device formed by carrying out patterning sequentially every time when a backside electrode layer, a photoelectric conversion layer and a transparent electrode layer are, respectively, formed on the surface of a substrate.

As a method for producing a solar cell module having a crystal type solar cell device, the following ones are known.
A method wherein on a front surface material, a sealing material film made of e.g. an ethylene/vinyl acetate copolymer (hereinafter referred to simply as EVA) is placed; thereon, a plurality of crystal type solar cell devices are arranged and wired; thereon, a sealing material film is placed; and a back surface material is laminated, to embed the crystal type solar cell devices in the sealing material.
A method wherein a liquid state curable resin is filled between a front surface material and a back surface material having a plurality of crystal type solar cell devices interposed therebetween, followed by curing the liquid state curable resin, to embed the crystal type solar cell devices in the sealing material made of such a curable resin (Patent Documents 1 and 2).

On the other hand, in the case of a thin-film type solar cell device, a glass substrate is usually employed as the substrate on which the thin-film type solar cell device is formed, and therefore, such a glass substrate can be used as the front surface material (or the back surface material). By forming a thin-film type solar cell device on the surface of a transparent substrate having a relatively large area and using such a glass substrate as the front surface material (or the back surface material), it is possible to easily and economically produce a solar cell module. In the case of thin-film type solar cell devices with small areas, like in the case of crystal type solar cell devices, it is possible to embed a substrate having thin-film type solar cell devices formed on its surface, in a sealing material between the front surface material and the back surface material. However, such a method is cumbersome and not economical.

As a method for producing a solar cell module wherein a glass substrate having a thin-film type solar cell device formed on its surface is used as the front surface material (or the back surface material), the following ones are known.

(1) A method wherein on the surface of a glass substrate on the side where a thin-film type solar cell device is formed, a sealing material film of EVA and a back surface material (or a front surface material) are stacked and laminated by heating and pressing in a reduced pressure atmosphere (Patent Document 3).

(2) A method wherein a glass substrate having a thin-film type solar cell device formed on its surface and a back surface material (or a front surface material) are permitted to face each other to form a laminate having its periphery except for one side sealed with e.g. a double sided adhesive tape, a liquid state curable resin composition is injected and filled into the laminate from the non-sealed side, the non-sealed side is sealed after the injection, and the curable resin composition is cured.

However, the method (1) have the following problems.
The EVA layer is exposed on the side surface of the produced solar cell module, whereby moisture or corrosive gas is likely to infiltrate from the interface between the EVA layer and the front surface material or the back surface material at the side surface.
At the time of laminating the sealing material film of EVA and the back surface material (or the front surface material) on the surface of the glass substrate on the side where the thin-film type solar cell device is formed, it is likely that an excessive pressure or heat is exerted to the thin-film type solar cell device, whereby the thin-film type solar cell device is likely to be damaged.
On the other hand, if the pressure or heat is suppressed to be low so that the thin-film type solar cell device will not be damaged, the interface bonding strength between the EVA layer and the thin-film type solar cell device, or the interface bonding strength between the EVA layer and the back surface material (or the front surface material) in the produced solar cell module tends to be inadequate, whereby peeling is likely to occur at the surface of the EVA layer, and further moisture or corrosive gas is more likely to infiltrate from the portion where the interface bonding strength is inadequate at the side surface of the solar cell module. Further, it is also likely that void spaces such as bubbles will remain between the EVA layer and the back surface material (or the front surface material).

Further, in the method (2), bubbles are likely to be formed inside of the produced solar cell module for the following reasons.
In the solar cell module having a thin-film type solar cell device, the thickness of the device portion is thin, and it is one of characteristics that the thickness of the module can be made thin. However, in the above laminate, the gap between the front surface material and the back surface material becomes narrow, whereby it becomes difficult to fill the liquid state curable resin composition, and spaces (bubbles) are likely to be formed where the curable resin composition is not filled in the gap.
Further, bubbles are likely to be formed also in the liquid state curable resin composition. Especially in a case where irregularities such as wirings are present on the surface of the thin-film type solar cell device, bubbles are likely to be formed on the surface of such irregularities.

And, once bubbles are formed inside of the solar cell module, the following problems will be brought about.
The interface bonding strength between the resin layer having the curable resin composition cured, and the thin-film type solar cell device, or the interface bonding strength between the resin layer and the back surface material (or the front surface material) tends to decrease.
In a case where bubbles are present on the side surface of the solar cell module, moisture or corrosive gas is likely to be infiltrated from the portion where the bubbles are present.
In a case where the thin-film type solar cell device is formed on the surface of the back surface material, a resin layer is formed on the transparent electrode layer side of the thin-film type solar cell device, whereby the resin layer is required to have high transparency. However, if bubbles are present in the resin layer, sunlight is likely to be irregularly reflected by the bubbles, and the amount of sunlight reaching the thin-film type solar cell device tends to decrease, whereby the power generation efficiency tends to decrease.
In the case of a see-through thin-film type solar cell module wherein a pair of electrodes interposing a photoelectric conversion layer as a layer made of a thin-film semiconductor are both made of transparent electrodes, bubbles remaining in the resin layer are readily visible, thus substantially impairing the product quality.

### PRIOR ART DOCUMENTS

### Patent Documents

Patent Document 1: JP-A-57-165411
Patent Document 2: JP-A-2001-339088
Patent Document 3: JP-A-11-87743

### DISCLOSURE OF INVENTION

### Technical Problem

The present invention is to provide a process for producing a solar cell module having a thin-film type solar cell device, whereby the thin-film type solar cell device is less susceptible to breakage, it is possible to increase an interface bonding strength between a resin layer and the thin-film type solar cell device and an interface bonding strength between the resin layer and surface materials, and it is possible to sufficiently suppress formation of bubbles by a liquid state curable resin composition.

### Solution to Problem

The present invention provides a process for producing a solar cell module as defined in the following [1] to [7].

[1] A process for producing a solar cell module comprising first and second surface materials, at least one of which has optical transparency, a resin layer interposed between the first and second surface materials, a thin-film type solar cell device formed on the surface, on the resin layer side, of at least one of the first and second surface materials, and a seal part enclosing the periphery of the resin layer, which process comprises the following Steps (a) to (d):

(a) a step of forming a seal part on the edge of a surface of a first surface material (provided that in a case where a thin-film type solar cell device is formed on a surface of the first surface material, the seal part is formed on the edge of the surface on the side where the thin-film solar cell device is formed),

(b) a step of supplying a liquid state curable resin composition to the region enclosed by the seal part of the first surface material,

(c) a step of laminating, in a reduced pressure atmosphere of not more than 100 Pa, a second surface material on the first surface material so as to be in contact with the curable resin composition formed on the first surface material thereby to obtain a laminated material having the curable resin composition hermetically sealed by the first and second surface materials and the seal part (provided that in a case where a thin-film type solar cell device is formed on a surface of the second surface material, the second surface material is laminated so that the surface on the side where the thin-film type solar cell device is formed, is in contact with the curable resin composition formed on the first surface material), and

(d) a step of curing the curable resin composition in such a state that the laminated material is placed in a pressure atmosphere of not less than 50 kPa to form a resin layer.

[2] The process according to [1], wherein one of the first and second surface materials is a glass substrate having a thin-film type solar cell device formed on its surface, and the other is a transparent surface material.
[3] The process according to [2], wherein the transparent surface material is a glass plate.
[4] The process according to any one of [1] to [3], wherein the pressure atmosphere of not less than 50 kPa is an atmospheric pressure atmosphere.
[5] The process according to any one of [1] to [4], wherein the curable resin composition is a photocurable resin composition.
[6] The process according to any one of [1] to [5], wherein the photocurable resin composition comprises at least one compound having, per molecule, from 1 to 3 groups selected from the group consisting of acryloyloxy groups and methacryloyloxy groups, and a photo-polymerization initiator.
[7] The process according to any one of [1] to [6], wherein the thin-film type solar cell device is a thin-film silicon solar cell device.

### Advantageous Effects of Invention

According to the process for producing a solar cell module of the present invention, the thin-film type solar cell device can be made to be less susceptible to breakage, it is possible to increase the interface bonding strength between the resin layer and the thin-film type solar cell device and the interface bonding strength between the resin layer and the surface materials, and it is possible to sufficiently suppress formation of bubbles by the liquid state curable resin composition.

### BRIEF DESCRIPTION OF DRAWINGS

FIG. 1 is a cross-sectional view illustrating an example of the first embodiment of the solar cell module in the present invention.

FIG. 2 is a cross-sectional view illustrating an example of the second embodiment of the solar cell module in the present invention.

FIG. 3 is a cross-sectional view illustrating an example of the third embodiment of the solar cell module in the present invention.

FIG. 4 is a plan view illustrating the state of Step (a) in the process of the present invention.

FIG. 5 is a cross-sectional view illustrating the state of Step (a) in the process of the present invention.

FIG. 6 is a plan view illustrating the state of Step (b) in the process of the present invention.

FIG. 7 is a cross-sectional view illustrating the state of Step (b) in the process of the present invention.

FIG. 8 is a cross-sectional view illustrating the state of Step (c) in the process of the present invention.

### DESCRIPTION OF EMBODIMENTS

In the present invention, the following definitions will apply.

The surface material on the sunlight-incident side is referred to as “the front surface material”, and the surface material on the backside of the front surface material is referred to as “the back surface material”.

The front surface material and the back surface material are generally referred to as “surface materials”.

Among the surface materials, the surface material wherein a seal part is formed on its edge and a liquid state curable resin composition is supplied to the region enclosed by the seal part in the process of the present invention, is referred to as “the first surface material”, and the surface material to be laminated on the curable resin composition is referred to as “the second surface material”.

A surface material having optical transparency is referred to as “a transparent surface material”.

A transparent surface material made of glass is referred to as “a glass plate”.

A surface material having a thin-film type solar cell device formed on its surface is referred to as “a substrate”, which is distinguished from a surface material having no thin-film type solar cell device formed on its surface.

A transparent surface material having a thin-film type solar cell device formed on its surface is referred to as “a transparent substrate”, which is distinguished from a transparent surface material having no thin-film type solar cell device formed on its surface.

A glass plate having a thin-film type solar cell device formed on its surface is referred to as “a glass substrate”, which is distinguished from a glass plate having no thin-film type solar cell device formed on its surface.

### <Solar Cell Module>

As the solar cell module in the present invention, the following three may be mentioned.

(A) A solar cell module having one layer of thin-film type solar cell device, wherein “a transparent substrate” having a thin-film type solar cell device formed on its surface is the front surface material, and “a surface material” having no thin-film type solar cell device formed on its surface, is the back surface material (first embodiment).

(B) A solar cell module having one layer of thin-film type solar cell device, wherein “a transparent surface material” having no thin-film type solar cell device formed on its surface is the front surface material, and “a substrate” having a thin-film type solar cell device formed on its surface is the back surface material (second embodiment).

(C) A solar cell module having two layers of thin-film type solar cell device, wherein “a transparent substrate” having a thin-film type solar cell device formed on its surface is the front surface material, and “a substrate” having a thin-film type solar cell device formed on its surface is the back surface material (third embodiment).

### First Embodiment

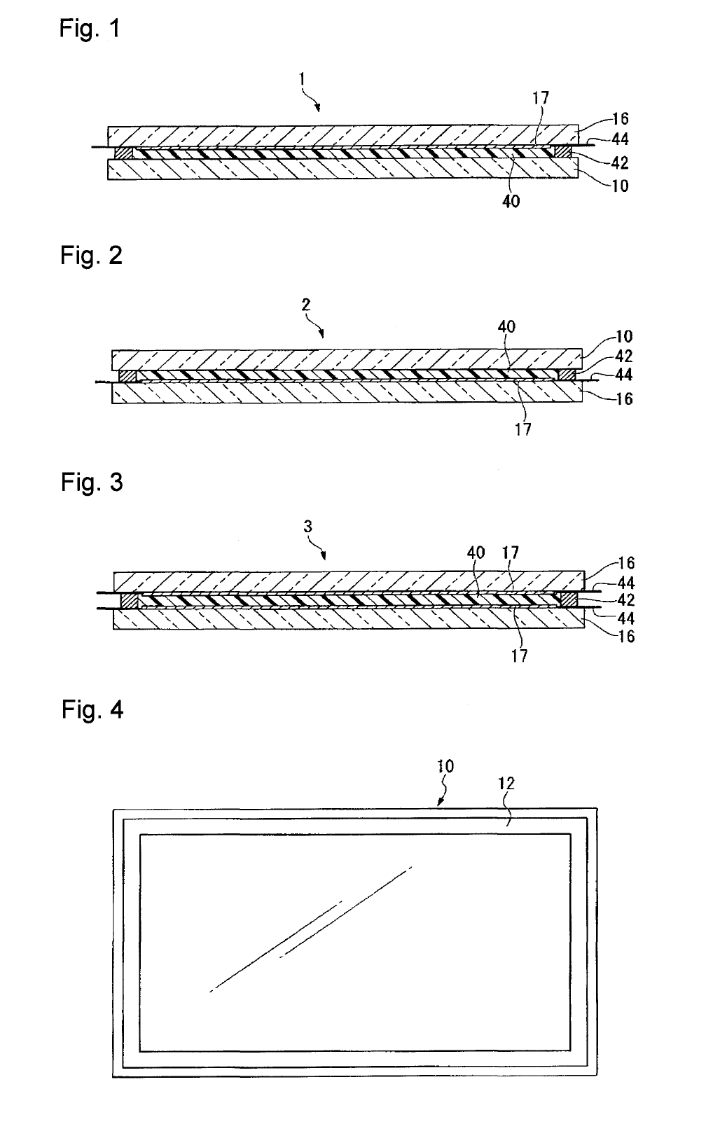

FIG. 1 is a cross-sectional view illustrating an example of the first embodiment of the solar cell module in the present invention.

The solar cell module 1 comprises a glass substrate 16 as the front surface material, a transparent surface material 10 as the back surface material, a resin layer 40 interposed between the glass substrate 16 and the transparent surface material 10, a thin-film type solar cell device 17 formed on the surface of the glass substrate 16 on the resin layer 40 side, a seal part 42 enclosing the periphery of the resin layer 40, and an electric wire 44 connected to the thin-film type solar cell device 17 and extending through the seal part 42 to the exterior. Here, in a case where the glass substrate 16 as the above front surface material becomes a second surface material, the transparent surface material 10 as the back surface material becomes a first surface material, and in a case where the glass substrate 16 as the above front surface material becomes a first surface material, the transparent surface material 10 as the back surface material becomes a second surface material.

### (Front Surface Material)

The front surface material is a transparent substrate which transmits sunlight.

A thin-film type solar cell device is formed on the surface of a transparent surface material at the region excluding its edge thereby to constitute the transparent substrate.

To the transparent surface material, surface treatment may be applied to improve the interface bonding strength with the seal part. The portion where such surface treatment is applied may be only the edge or may be the entire surface of the surface material. The method for the surface treatment may, for example, be a method of treating the surface of the transparent surface material with a silane coupling agent, or treatment to form a thin film of silicon oxide via an oxidizing flame by a flame burner.

As the transparent substrate, the glass substrate 16 as shown in the Fig. or a transparent resin substrate may be mentioned, and a glass substrate is most preferred not only from the viewpoint such that the transparency to sunlight is high, but also from such a viewpoint that it has durability against the production process of a thin-film type solar cell device such as heat resistance, light resistance, weather resistance, corrosion resistance, scratch resistance and high mechanical strength.

As the material for the glass plate of the glass substrate, a glass material such as soda lime glass may, for example, be mentioned.

As the material for the transparent resin plate of the transparent resin substrate, a highly transparent resin material (such as polycarbonate or polymethyl methacrylate) may be mentioned. In the case of a resin substrate, it is required to form a thin-film type solar cell device on the substrate at a temperature of not higher than the heat resistant temperature of the resin material.

The thickness of the transparent substrate including the thickness of the thin-film type solar cell device is usually from 1 to 6 mm in the case of a glass substrate, and is usually from 0.1 to 3 mm in the case of a transparent resin substrate. In such a thickness, the thickness of the thin-film type solar cell device is usually not more than 10 μm

As the glass substrate in the present invention, a commercially available glass substrate having a thin-film type solar cell device may be obtained and used.

### (Thin-Film Type Solar Cell Device)

A thin-film type solar cell device is formed on the surface of a transparent surface material at the region excluding the edge, thereby to constitute a transparent substrate. Further, wiring terminals to take out an electric power from the thin-film type solar cell device are formed at the edge on the surface of the transparent substrate. The after-described seal part is provided at the edge of the transparent substrate where the thin-film type solar cell device is not formed and overlaps with part of the surface of wirings or part of the surface of the terminals.

The thin-film type solar cell device is formed sequentially by carrying out patterning every time when the respective layers of a transparent electrode layer, a photoelectric conversion layer and a backside electrode layer are formed on the surface of a transparent surface material, followed by wiring to constitute the transparent substrate.

The material for the transparent electrode layer may, for example, be indium tin oxide or tin oxide.

The photoelectric conversion layer is a layer made of a thin film semiconductor. The thin film semiconductor may, for example, be an amorphous silicon type semiconductor, fine crystal silicon type semiconductor, a compound semiconductor (such as a chalcopyrite type semiconductor or CdTe type semiconductor) or an organic type semiconductor.

The material for the backside electrode layer may, for example, be a material having no optical transparency (such as silver or aluminum) or a material having optical transparency (such as indium tin oxide, tin oxide or zinc oxide).

As the thin-film type solar cell device, in a case where a photoelectric conversion layer is formed on a transparent electrode layer to carry out power generation by incident tight from the surface material, a thin-film silicon solar cell device is preferred wherein the thin film semiconductor is an amorphous silicon type semiconductor.

### (Back Surface Material)

As the back surface material, the transparent surface material 10 as shown in the drawings is preferred, since it transmits light to cure the photocurable resin composition. However, in a case where the thin-film type solar cell device has optical transparency, (i.e. in a case where the material for the backside electrode layer is optically transparent indium tin oxide or tin oxide), light to cure the photocurable resin composition can be transmitted from the front surface material side, whereby the rear surface material may be a non-transparent surface material (such as a metal plate or a ceramics plate).

The transparent surface material may have sufficient transparency to let light transmit to cure the photocurable resin composition. Further, the transparent surface material may have the weather resistance, corrosion resistance and high mechanical strength required for the back surface material. As such a transparent surface material, a glass plate or a transparent resin plate may be mentioned, and a glass plate is preferred since the gas permeability is low, and it has high mechanical strength.

The material for the glass plate may be the same as the above-mentioned material for the glass substrate.

The material for the transparent resin plate may be a resin material to let light transmit to cure the photocurable resin composition, and in addition to the above-mentioned resin material having high transparency, a resin material having low transparency to light other than ultraviolet rays and visible light of at most 450 nm may be used.

To the transparent surface material, surface treatment may be applied in order to improve the interface bonding strength with the resin layer. The method for such surface treatment may, for example, be a method of treating the surface of a glass plate with a silane coupling agent, or treatment to form a thin film of silicon oxide via an oxidizing flame by a flame burner.

The thickness of the transparent surface material is usually from 1 to 6 mm in the case of a glass plate, and usually from 0.1 to 3 mm in the case of a transparent resin plate, from the viewpoint of the mechanical strength and transparency.

### (Resin Layer)

The resin layer is a layer which plays a role of laminating the front surface material and the back surface material and sealing the thin-film type solar cell device between the front surface material and the back surface material, and it is a layer formed by curing the after-described curable resin composition.

The thickness of the resin layer is not particularly limited and may be adjusted to be a necessary thickness depending upon the particular purpose. According to the process of the present invention, the thickness of the resin layer can be made thin as compared with a conventional process, and therefore, the process of the present invention is suitable particularly for the production of a solar cell module having a thin resin layer.

The thickness of the resin layer is preferably from 0.01 to 2 mm, particularly preferably from 0.1 to 0.8 mm.

A method for adjusting the thickness of the resin layer may, for example, be a method of adjusting the thickness of the after-described seal part, or a method of providing between the front surface material and the back surface material a member to adjust the thickness separate from the seal part. For example, in a case where a double sided adhesive tape is employed as the seal part, the thickness of the resin layer can be determined by using a double sided adhesive tape having a thickness which meets the purpose. In a case where a seal part made of a material, of which the thickness is changeable by a compression force (such as an elastic material or a non-cured curable resin composition) is to be used, spacer particles having a prescribed particle diameter may be disposed at the seal part.

### (Seal Part)

The seal part is one made of the after-described seal member (such as a double sided adhesive tape or a curable resin composition).

### (Shape)

The shape of a solar cell module is usually rectangular.

Since the process of the present invention is suitable particularly for the production of a solar cell module having a large area, the size of the solar cell module is suitably at least 0.6 m×0.6 m, preferably at least 0.8 m×0.8 m. The upper limit in the size of the solar cell module is determined in many cases by the limitation in size of the production apparatus such as a reduced pressure apparatus. Further, if the solar cell module is too large, its handling in e.g. installation tends to be difficult. From such restrictions, the upper limit in the size of the solar cell module is usually at a level of 3×3 m.

The shape and size of the front surface material and the back surface material are substantially equal to the shape and size of the solar cell module, and the shapes or sizes of the front surface material and the back surface material may be different to some extent.

### Second Embodiment

FIG. 2 is a cross-sectional view illustrating an example of the second embodiment of the solar cell module in the present invention.

The solar cell module 2 comprises a transparent surface material 10 as the front surface material, a glass substrate 16 as the back surface material, a resin layer 40 interposed between the transparent surface material 10 and the glass substrate 16, a thin-film type solar cell device 17 formed on the surface, on the resin layer 40 side, of the glass substrate 16, a seal part 42 enclosing the periphery of the resin layer 40, and an electric wire 44 connected to the thin-film type solar cell device 17 and extending through the seal part 42 to the exterior. Here, in a case where the transparent surface material 10 as the above front surface material becomes a second surface material, the glass substrate 16 as the back surface material becomes a first surface material, and in a case where the transparent surface material 10 as the above surface material becomes a first surface material, the glass substrate 16 as the back surface material becomes a second surface material.

In the second embodiment, with respect to the same construction as in the first embodiment, its description will be omitted.

### (Front Surface Material)

The front surface material is a transparent material which transmits sunlight.

The transparent surface material may, for example, be a glass plate or a transparent resin plate, and a glass plate is most preferred not only from such a viewpoint that the transparency to sunlight is high, but also from such a viewpoint that it has light resistance, weather resistance, corrosion resistance, scratch resistance and high mechanical strength. A transparent surface material is preferred also from such a viewpoint that the photocurable resin composition can be cured by incident light from the front surface material.

As the material for the glass plate, in addition to soda lime glass, a glass material such as a highly transparent glass (white plate) having a lower iron content with a lower bluish color is more preferred. As a front surface material to increase safety, strengthened glass may be employed. In a case where an especially thin glass plate is required, strengthened glass obtainable by a chemical strengthening method may be employed. For example, in a case where the thickness of the transparent surface material is not more than 1.5 mm, it is preferred to use strengthened glass by a chemical strengthening method, since the mechanical strength can thereby be improved.

The material for a transparent resin plate may, for example, be a highly transparent resin material (such as polycarbonate or polymethyl methacrylate).

To the transparent surface material, surface treatment may be applied in order to improve the interface bonding strength with the resin layer. A method for such surface treatment may, for example, be a method of treating the surface of a glass plate with a silane coupling agent, or treatment to form a thin film of silicon oxide via an oxidizing flame by a flame burner.

The thickness of the transparent surface material is usually from 1 to 6 mm in the case of a glass plate, and usually from 0.1 to 3 mm in the case of a transparent resin plate, from the viewpoint of the mechanical strength and transparency.

### (Back Surface Material)

As the back surface material, a glass plate as shown in the drawings is preferred from such a viewpoint that a thin-film type solar cell device is formed on its surface. However, a resin plate may also be employed, in a case where the thin-film type solar cell device can be formed at a temperature lower than the heat resistant temperature of the resin plate e.g. by applying an ink containing a compound semiconductor, or a non-transparent surface material (such as a metal plate of e.g. stainless steel provided with an insulating layer or a ceramics plate) may be used.

The transparent substrate may have weather resistance, corrosion resistance, high mechanical strength, etc. required for the back surface material. As the transparent surface material for such a transparent substrate, a glass plate of e.g. soda lime glass is preferred.

As the material for the glass plate for the glass substrate, the same as the material for the above-described glass plate may be mentioned.

As the glass substrate in the present invention, a commercially available glass substrate having a thin-film type solar cell device may be obtained and used.

The transparent substrate is constructed by forming a thin-film type solar cell device on the surface of the transparent surface material at the region excluding the edge.

To the transparent surface material, surface treatment may be applied in order to improve the interface bonding strength with the seal part. The portion where such surface treatment is applied may be only the edge or on the entire surface of the surface material. A method for the surface treatment may, for example, be a method of treating the surface of the transparent surface material with a silane coupling agent, or treatment to form a thin film of silicon oxide via an oxidizing flame by a flame burner.

The thickness of the transparent substrate including the thickness of the thin-film type solar cell device is usually from 1 to 6 mm in the case of a glass substrate and usually from 0.1 to 3 mm in the case of a transparent resin substrate or a metal substrate provided with an insulating layer. In such a thickness, the thickness of the thin-film type solar cell device is usually not more than 10 μm.

### (Thin-Film Type Solar Cell Device)

The thin-film type solar cell device is formed sequentially by carrying out patterning every time when the respective layers of the backside electrode layer, the photoelectric conversion layer and the transparent electrode layer on the surface of the back surface material, followed by wiring to obtain a substrate. As the case requires, a buffer layer may be formed between the photoelectric conversion layer and the transparent electrode layer. As a thin-film type solar cell device wherein power generation is carried out by incident light from the transparent electrode layer as the uppermost layer, a chalcopyrite type or CdTe type compound semiconductor solar cell device is preferred. In a case where the chalcopyrite type semiconductor is CuInGaSe₂, CdS or ZnO can be used as the buffer layer.

### Third Embodiment

FIG. 3 is a cross-sectional view illustrating an example of the third embodiment of the solar cell module in the present invention.

The solar cell module 3 comprises a glass substrate 16 as the front surface material, a glass substrate 16 as the back surface material, a resin layer 40 interposed between the pair of glass substrates, a total of two layer thin-film type solar cell devices 17 formed on the surfaces, on the resin layer 40 side, of the respective glass substrates 16, a seal part 42 enclosing the periphery of the resin layer 40, and electric wires 44 connected to the thin-film type solar cell devices 17 and extend through the seal part 42 to the exterior. Here, in a case where the glass substrate 16 as the above front surface material becomes a second surface material, the glass substrate 16 as the back surface material becomes a first surface material, and in a case where the glass substrate 16 as the above front surface material becomes a first surface material, the glass substrate 16 as the back surface material becomes a second surface material.

As the glass substrate in the present invention, a commercially available glass substrate having a thin-film type solar cell device may be obtained and used.

In the third embodiment, with respect to the same construction as in the first embodiment and the second embodiment, its description will be omitted.

### (Surface Materials)

As the front surface material, it is possible to employ the same transparent substrate as the front surface material in the first embodiment, and the glass substrate 16 as shown in the drawings is most preferred.

As the back surface material, it is possible to employ the same substrate (the transparent substrate or the non-transparent substrate) as the back surface material in the second embodiment, and a transparent substrate is preferred, and the glass substrate 16 as shown in the drawings is more preferred.

### (Thin-Film Type Solar Cell Device)

The thin-film type solar cell device on the front surface material side is formed sequentially by carrying out patterning every time when the respective layers of the transparent electrode layer, the photoelectric conversion layer and the backside electrode layer are formed on the surface of a transparent surface material, followed by wiring to obtain a transparent substrate.

As the material for the backside electrode layer, it is necessary to employ a material having optical transparency (such as indium tin oxide or tin oxide) in order to let at least part of sunlight transmit to the thin-film type solar cell device on the back surface material side. In such a case, a thin-film silicon solar cell device is preferred wherein the thin-film semiconductor is an amorphous silicon type semiconductor.

The thin-film type solar cell device on the back surface material side is formed sequentially by carrying out patterning every time when the respective layers of the backside electrode layer, the photoelectric conversion layer and the transparent electrode layer are formed on the surface of the back surface material, followed by wiring to obtain a substrate. From the viewpoint of utilizing incident light from the transparent electrode layer, as the thin-film semiconductor, a chalcopyrite type or CdTe type compound semiconductor solar cell device is preferred.

As the material for the backside electrode layer, it is required to employ a material having optical transparency (such as indium tin oxide or tin oxide) in a case where light to cure the photocurable resin composition is transmitted from the back surface material side.

Further, as the back surface material, it is possible to employ the same transparent substrate as the front surface material. In such a case, it is possible to utilize incident light from the front surface material and the back surface material for power generation.

### <Process for Producing Solar Cell Module>

The process for producing a solar cell module of the present invention is a process comprising the following Steps (a) to (d):

(a) a step of forming a seal part on the edge of a surface of a first surface material (provided that in a case where a thin-film type solar cell device is formed on a surface of the first surface material, the seal part is formed on the edge of the surface on the side where the thin-film solar cell device is formed),

(b) a step of supplying a liquid state curable resin composition to the region enclosed by the seal part of the first surface material,

(c) a step of laminating, in a reduced pressure atmosphere of not more than 100 Pa, a second surface material on the first surface material so as to be in contact with the curable resin composition formed on the first surface material thereby to obtain a laminated material having the curable resin composition hermetically sealed by the first and second surface materials and the seal part (provided that in a case where a thin-film type solar cell device is formed on a surface of the second surface material, the second surface material is laminated so that the surface on the side where the thin-film type solar cell device is formed, is in contact with the curable resin composition formed on the first surface material), and

(d) a step of curing the curable resin composition in such a state that the laminated material is placed in a pressure atmosphere of not less than 50 kPa to form a resin layer.

The process of the present invention is a process wherein the liquid state curable resin composition is sealed between the first and second surface materials in a reduced pressure atmosphere, and then, the sealed curable resin composition is cured in a high pressure atmosphere such as an atmospheric air atmosphere to form the resin layer. The sealing of the curable resin composition under reduced pressure is not a method of injecting the curable resin to a wide space with a narrow gap between the first and second surface materials but a method for supplying the curable resin composition substantially over the entire surface of the first surface material and then laminating the second surface material to seal the curable resin composition between the first and second surface materials.

With respect to the method for sealing a liquid state curable resin composition under reduced pressure and curing the curable resin composition under atmospheric pressure, reference is made, for example, to the method for producing a laminated safety glass and the photocurable resin composition to be used in the method, as disclosed in WO2008/81838 or WO2009/16943.

### (Step (a))

Firstly, a seal part is formed along the peripheral portion on one surface of the first surface material. It is optional to use the back surface material or the front surface material as the first surface material.

In a case where the first surface material is “a surface material” having no thin-film type solar cell device formed thereon, the surface on which the seal part is to be formed is either one of the two surfaces. In a case where the two surfaces are different in nature, one surface having a necessary nature is selected for use. For example, in a case where surface treatment to improve the interface adhesive strength with the resin layer is applied to one surface, the seal part is formed on such a surface. Further, in a case where an antireflection layer is formed on one surface, the seal part is formed on the rear side thereof.

In a case where the first surface material is “a substrate” having a thin-film type solar cell device formed thereon, the surface on which the seal part is to be formed, is the surface on the side where the thin-film type solar cell device is formed.

The seal part is required to have an interface bonding strength sufficient to prevent leakage of the liquid state curable resin composition from the interface of the seal part and the first surface material and from the interface between the seal part and the second surface material in the after-described Step (c), and rigidity sufficient to maintain the shape. Accordingly, the seal part is preferably a seal member having an adhesive or tackifier on its surface. As such a seal member, the following ones may be mentioned.
A tape- or rod-form elongated member having an adhesive layer or a tackifier layer preliminarily provided on its surface (such as a double sided adhesive tape).
One wherein an adhesive layer or a tackifier layer is formed along the edge on a surface of the first surface material and an elongated member is bonded thereto.
Using a curable resin composition, a dam-form seal precursor is formed by printing or dispensing along the edge on a surface of the first surface material, followed by curing the curable resin composition, and then, an adhesive layer or a tackifier layer is formed on its surface.

Further, as the seal member, a high viscosity curable resin composition may be used without curing. As such a high viscosity curable resin composition, a photocurable resin composition is preferred. Further, in order to maintain a space between the first and second surface materials, spacer particles having a prescribed particle size may be incorporated to the curable resin composition. The seal part formed from the curable resin composition to form the seal part, may be cured at the same time as curing of the curable resin composition to form the resin layer, or may be cured before curing the curable resin composition to form the resin layer.

In order to form a prescribed space between the first and second surface materials i.e. in order to make the resin layer to have a prescribed thickness, a necessary amount of the non-cured curable resin composition is supplied to the region enclosed by the seal part on the first surface material. In a case where a high viscosity curable resin composition is used without curing as the seal member, it is preferred to form it slightly thicker than the prescribed thickness of the above-mentioned resin layer.

### (Step (b))

After the Step (a), a liquid state curable resin composition is supplied to the region enclosed by the seal part.

The amount of the curable resin composition to be supplied is preliminarily set to be such an amount that the space formed by the first and second surface materials is filled by the curable resin composition. At that time, preliminarily, taking into consideration the volume reduction due to curing shrinkage of the curable resin composition, the volume of the resin layer after curing can be set.

The supplying method may, for example, be a method wherein the first surface material is placed horizontal, and the curable resin composition is supplied in a dotted form, a line form or a planar form by a supplying means such as a dispenser or a die coater.

In the process of the present invention, as compared with a conventional method for injecting a curable resin to a space, it is possible to employ a high viscosity curable resin composition or a curable resin composition containing a high molecular weight curable compound (such as an oligomer).

By a high molecular weight curable compound, the number of chemical bonds in the curable resin composition can be made small, and accordingly, curing shrinkage of the resin layer upon curing the curable resin composition can be made small, and the mechanical strength can be improved. On the other hand, many of high molecular weight curable compounds have a high viscosity. Therefore, from the viewpoint of suppressing residual bubbles while securing the mechanical strength of the resin layer, it is preferred to adjust the viscosity by dissolving a curable monomer having a smaller molecular weight in the high molecular weight curable compound. However, by using a curable monomer having a small molecular weight, the curing shrinkage of the resin layer tends to increase or the mechanical strength tends to decrease, although the viscosity of the curable resin composition can be lowered.

In the present invention, it is possible to employ a relatively high viscosity curable resin composition, whereby it is possible to reduce the curing shrinkage and to improve the mechanical strength. The viscosity of the photocurable resin composition at 40° C. is preferably not higher than 50 Pa·s.

The curable resin composition is preferably a photocurable resin composition. As compared with a thermosetting resin, a photocurable resin composition is cured in a short time by a less amount of thermal energy. Accordingly, by using the photocurable resin composition, the environment load to the thin-film type solar cell device will decrease. Further, the photocurable resin composition can be substantially cured in a few minutes to a few tens minutes, whereby the efficiency for the production of the solar cell module is high.

The photocurable resin composition is a material which is curable by an action of light to form a resin layer. As such a photocurable resin composition, the following ones may, for example, be mentioned and may be used within a range wherein the hardness of the resin layer will not be too high.
A composition comprising a compound having an addition-polymerizable unsaturated group and a photopolymerization initiator.
A composition containing a polyene compound having from 1 to 6 unsaturated groups (such as a triallylisocyanurate) and a polythiol compound having from 1 to 6 thiol groups (triethylene glycol dimercaptan) in such a ratio that the numbers of moles of the unsaturated groups and the thiol groups are substantially equal, and further containing a photopolymerization initiator.
A composition comprising an epoxy compound having at least two epoxy groups, and a photo-cation-generating agent.

The photocurable resin composition is more preferably one comprising at least one compound having a group (hereinafter referred to as a (meth)acryloyloxy group) selected from an acryloyloxy group and a methacryloyloxy group, and a photopolymerization initiator, since the curing rate is high, and the transparency of the resin layer will be high.

The compound having a (meth)acryloyloxy group (hereinafter referred to also as a (meth)acrylate compound) is preferably a compound having from 1 to 6 (meth)acryloyloxy groups per molecule, particularly preferably a compound having from 1 to 3 (meth)acryloyloxy groups per molecule, since the resin layer will not be too hard.

The (meth)acrylate compound is preferably an aliphatic or alicyclic compound not containing an aromatic ring as far as possible, from the viewpoint of the light resistance of the resin layer.

The (meth)acrylate compound is more preferably a compound having a hydroxy group with a view to improving the interface bonding strength. The content of the (meth)acrylate compound having a hydroxy group is preferably at least 25 mass %, more preferably at least 40 mass % in all (meth)acrylate compounds. On the other hand, a compound having a hydroxy group tends to have a high elastic modulus after curing, and particularly in a case where a methacrylate having a hydroxy group is employed, the cured product is likely to be too hard. Therefore, the content of the methacrylate having a hydroxy group is preferably at most 70 mass %, more preferably at most 60 mass %, in all (meth)acrylate compounds.

The (meth)acrylate compound may be a relatively low molecular weight compound (hereinafter referred to as a (meth)acrylate monomer) or a relatively high molecular weight compound having repeating units (hereinafter referred to as a (meth)acrylate oligomer).

The (meth)acrylate compound may, for example, be one composed of at least one (meth)acrylate monomer, one composed of at least one (meth)acrylate oligomer, or one composed of at least one (meth)acrylate monomer and at least one (meth)acrylate oligomer, preferably one composed of at least one acrylate oligomer, or one composed of at least one acrylate oligomer and at least one (meth)acrylate monomer. For the purpose of increasing the adhesion between the thin-film type solar cell device and the resin layer, particularly preferred is a curable resin composition comprising an urethane type oligomer having an average of from 1.8 to 4 curable functional groups, per molecule, selected from one or both of acryloyloxy groups and methacryloyloxy groups, and a hydroxyalkyl methacrylate having a C₃₋₈ hydroxyalkyl group wherein the number of hydroxy groups is 1 or 2.

In consideration of the fact that the photocurable resin composition will be placed in a reduced pressure atmosphere in a reduced pressure apparatus, the (meth)acrylate monomer is preferably a compound having a low vapor pressure so that the volatility can sufficiently be suppressed. In a case where the curable resin composition contains a (meth)acrylate monomer having no hydroxy group, it is possible to employ a C₈₋₂₂ alkyl(meth)acrylate, or a mono(meth)acrylate or di(meth)acrylate of a relatively low molecular weight polyether diol such as polyethylene glycol or polypropylene glycol, preferably a C₈₋₂₂ alkyl methacrylate.

The (meth)acrylate oligomer is preferably a (meth)acrylate oligomer of a molecular structure having a chain with at least two repeating units (such as a polyurethane chain, a polyester chain, a polyether chain, a polycarbonate chain or the like) and a (meth)acryloyloxy group. Such a (meth)acrylate oligomer may, for example, be a (meth)acrylate oligomer having an urethane bond (usually further containing a polyester chain or a polyether chain) and at least two (meth)acryloyloxy groups, so-called an urethane acrylate oligomer. Such an urethane acrylate oligomer is preferred since the mechanical performance of the resin after curing, the adhesion with the substrate, etc. can widely be adjusted by the molecular design of the urethane chain.

The number average molecular weight of the (meth)acrylate oligomer is preferably from 1,000 to 100,000, more preferably from 10,000 to 70,000. When the number average molecular weight is at least 1,000, the crosslinked density of the resin layer after the curing tends to be low, and the flexibility of the resin layer will be good. Further, when the number average molecular weight is at most 100,000, the viscosity of the curable resin composition will be low. In a case where the viscosity of the (meth)acrylate oligomer is too high, it is preferred to use a (meth)acrylate monomer in combination thereby to lower the viscosity as the entire (meth)acrylate compound.

The (meth)acrylate oligomer is more preferably an acrylate oligomer whereby the reactivity in curing can be increased.

The photopolymerization initiator may, for example, be a photopolymerization initiator of e.g. acetophenone type, ketal type, benzoin or benzoin ether type, phosphine oxide type, benzophenone type, thioxanthone type or quinone type, and a photopolymerization initiator of acetophenone type or phosphine oxide type is preferred. In a case where curing is carried out by visible light having a short wavelength, a photopolymerization initiator of phosphine oxide type is more preferred from the viewpoint of the absorption wavelength region of the photopolymerization initiator.

The photo-cation-generating agent may, for example, be a compound of onium salt type.

The curable resin composition may contain various additives such as a polymerization inhibitor, photocuring accelerator, a chain transfer agent, a photostabilizer (such an ultraviolet absorber or a radical-capturing agent), an antioxidant, a flame retardant, an adhesive improving agent (such as a silane coupling agent), a pigment, a dye, etc., as the case requires, and it preferably contains a polymerization inhibitor and a photostabilizer. Particularly, by containing a polymerization inhibitor in an amount smaller than the polymerization initiator, it is possible to improve the stability of the curable resin composition and to adjust the molecular weight of the resin layer after curing.

However, in the case of the solar cell module of the second embodiment or the third embodiment, sunlight is permitted to pass through the resin layer formed by curing of the curable resin composition, and therefore, it is undesirable to contain an additive which may hinder the transmission of sunlight. For example, an ultraviolet absorber is likely to absorb ultraviolet components of sunlight to be transmitted thereby to lower the amount of light incident to the solar cell device. However, on the other hand, the resin layer through which sunlight will pass, is required to have light resistance, particularly durability against light having a short wavelength such as ultraviolet rays. Accordingly, in a case where an ultraviolet absorber or the like is to be incorporated, it is advisable to suitably adjust the absorption properties, the blend amount, etc.

In order to increase the adhesion between the thin-film type solar cell device and the resin layer or in order to adjust the elastic modulus of the resin layer, it is preferred to incorporate a chain transfer agent. A chain transfer agent having a thiol group in its molecule is particularly preferred.

The polymerization inhibitor may, for example, be a polymerization inhibitor of e.g. hydroquinone type (such as 2,5-di-t-butyl hydroquinone), cathechol type (such as p-t-butyl cathechol), anthraquinone type, phenothiazine type or hydroxytoluene type.

The photostabilizer may, for example, be an ultraviolet absorber (such as benzotriazole type, benzophenone type or salicylate type) or a radical-capturing agent (hindered amine type).

The antioxidant may, for example, be a compound of phosphorus type or sulfur type.

Since the curable resin composition is placed in a reduced pressure atmosphere, the photopolymerization initiator and various additives are preferably compounds which have a relatively large molecular weight and a small vapor pressure under reduced pressure.

### (Step (c))

After the Step (b), the first surface material having the curable resin composition supplied, is introduced into a reduced pressure apparatus, and the first surface material is flatly placed on a fixed support table in the reduced pressure apparatus so that the surface of the curable resin composition faces upward.

At an upper portion in the reduced pressure apparatus, a vertically movable support mechanism is provided, and the second surface material is attached to the movable support mechanism. In a case where a thin-film type solar cell device is formed on the surface of the second surface material, the surface on the side where the thin-film type solar cell device is formed is permitted to face downward.

The second surface material is located above the first surface material and at a position not in contact with the curable resin composition. That is, the curable resin composition on the first surface material and the second surface material (the thin-film type solar cell device in a case where the thin-film type solar cell device is formed thereon) are permitted to face each other without being in contact with each other.

Otherwise, a vertically movable support mechanism may be provided at a lower portion in the reduced pressure apparatus, and the first surface material having the curable resin composition supplied, may be placed on the movable support mechanism. In such a case, the second surface material is attached to a fixed support table provided at an upper portion in the reduced pressure apparatus, and the first and second surface materials are permitted to face each other.

Further, both the first and second surface materials may be supported by movable support mechanisms provided one above the other in the reduced pressure apparatus.

After positioning the first and second surface materials at prescribed positions, the interior of the reduced pressure apparatus is depressurized to a prescribed reduced pressure atmosphere. If possible, during the depressurizing operation or after depressurized to the reduced pressure atmosphere, the first and second surface materials may be positioned at the prescribed positions in the reduced pressure apparatus.

After the interior of the reduced pressure apparatus becomes a reduced pressure atmosphere, the second surface material supported by the mobile support mechanism is moved downward to laminate the second surface material on the curable resin composition on the first surface material.

By such laminating, the curable resin composition is sealed in a space defined by the surface of the first surface material (in a case where a thin-film type solar cell device is formed on the first surface material, the surface on the side where the thin-film type solar cell device is formed), the surface of the second surface material (in a case where a thin-film type solar cell device is formed on the second surface material, the surface on the side where the thin-film type solar cell device is formed) and the seal part.

At the time of such laminating, the curable resin composition is spread by the own weight of the second surface material, the pressing pressure from the movable support mechanism, etc., so that the curable resin composition is filled in the above-mentioned space, and thereafter, at the time of exposing it to the high pressure atmosphere in Step (d), a layer of the curable resin composition with little or no air bubbles will be formed. Hereinafter, the laminated material will be referred to also as “a laminate precursor”.

At the time of the laminating, the reduced pressure atmosphere is not more than 100 Pa and preferably at least 10 Pa. If the pressure of the reduced pressure atmosphere is too low, such a reduced pressure atmosphere may adversely affect the respective components (such as a curable compound, a photopolymerization initiator, a polymerization inhibitor, a photostabilizer, etc.) contained in the curable resin composition. For example, if the pressure of the reduced pressure atmosphere is too low, the respective components are likely to vaporize, or it may take time to provide such a reduced pressure atmosphere. The pressure of the reduced pressure atmosphere is more preferably from 15 to 40 Pa.

The period of time from the time when the first and second surface materials are laminated to the release of the reduced pressure atmosphere is not particularly limited, and the reduced pressure atmosphere may be released immediately after sealing of the curable resin composition, or after sealing of the curable resin composition, the reduced pressure state may be maintained for a prescribed time. By maintaining the reduced pressure state for a prescribed time, the curable resin composition tends to flow in the sealed space, and the distance between the first and the second surface materials becomes uniform, whereby even if the atmosphere pressure is increased, the sealed state may easily be maintained. The period of time for maintaining the reduced pressure state may be a long time of at least a few hours, but from the viewpoint of the production efficiency, it is preferably within 1 hour, more preferably within 10 minutes.

### (Step (d))

After releasing the reduced pressure atmosphere in Step (c), the laminate precursor is placed in a pressure atmosphere wherein the pressure of the atmosphere is not less than 50 kPa.

When the laminate precursor is placed in a pressure atmosphere of not less than 50 kPa, the first and second surface materials are pressed by the increased pressure in a direction to closely adhere to each other, whereby if air bubbles are present in the sealed space in the laminate precursor, the curable resin composition tends to flow into the air bubbles, and the entire sealed space will be uniformly filled by the curable resin composition.

The pressure atmosphere is usually from 80 kPa to 120 kPa. The pressure atmosphere may be an atmospheric pressure atmosphere or may be a pressure higher than the atmospheric pressure atmosphere. The atmospheric air atmosphere is most preferred from such a viewpoint that the operation of e.g. curing the curable resin composition can be carried out without requiring any special installation.

The period of time (hereinafter referred to as the high pressure retention time) from the time when the laminate precursor is placed in a pressure atmosphere of not less than 50 kPa to the initiation of the curing of the curable resin composition is not particularly limited. In a case where a process of taking out the laminate precursor from the reduced pressure apparatus and transferring it to a curing apparatus, and then initiating the curing, is carried out in an atmospheric pressure atmosphere, the time required for such a process is the high pressure retention time. Accordingly, in a case where at the time when the laminate precursor is placed in the atmospheric air atmosphere, air bubbles are already not present in the sealed space of the laminate precursor, or air bubbles have disappeared during the process, the curable resin composition can be immediately cured. In a case where it takes time until air bubbles disappear, the laminated precursor is held in the atmosphere under a pressure of not less than 50 kPa until the air bubbles disappear. Further, usually, there will be no trouble even if the high pressure retention becomes long, and therefore, the high pressure retention time may be prolonged from other necessity of the process. The high pressure retention time may be as long as more than one day, but from the viewpoint of the production efficiency, it is preferably within 6 hours, more preferably within 1 hour, and from the viewpoint of high production efficiency, it is particularly preferably within 10 minutes.

In a case where the curable resin composition is a photocurable resin composition, the photocurable resin composition in the laminate precursor is irradiated with light for curing, whereby a solar cell module is produced. For example, by applying ultraviolet rays or visible light with a short wavelength from a light source (such as an ultraviolet lamp or a high pressure mercury lamp), the photocurable resin composition is cured. By the curing of the photocurable resin composition, a resin layer will be formed as a sealing material for the solar cell module.

The light is applied from the side having optical transparency as between the first surface material (including the first surface material having a thin-film type solar cell device is formed) and the second surface material (including the second surface material having a thin-film type solar cell device is formed). When both materials have optical transparency, the light may be applied from both sides.

The light is preferably ultraviolet rays or visible light with a wavelength of at most 450 nm.

### Specific Examples

In the process of the present invention, it is optional to use the back surface material or the front surface material as the first surface material. Accordingly, the solar cell modules of the first to third embodiments (examples as shown in the drawings) can be produced by the following two methods, depending upon the selection of the first surface material.

With respect to the first embodiment:

(A-1) A method of using a transparent surface material 10 (the back surface material) as the first surface material, and a glass substrate 16 (the front surface material) as the second surface material.

(A-2) A method of using a glass substrate 16 (the front surface material) as the first surface material, and a transparent surface material 10 (the back surface material) as the second surface material.

With respect to the second embodiment:

(B-1) A method of using a glass substrate 16 (the back surface material) as the first surface material, and a transparent surface material 10 (the front surface material) as the second surface material.

(B-2) A method of using a transparent surface material 10 (the front surface material) as the first surface material, and a glass substrate 16 (the back surface material) as the second surface material.

With respect to the third embodiment:

(C-1) A method of using a glass substrate 16 (the back surface material) as the first surface material, and a glass substrate 16 (the front surface material) as the second surface material.

(C-2) A method of using a glass substrate 16 (the front surface material) as the first surface material, and a glass substrate 16 (the back surface material) as the second surface material.

Now, taking the case of the method (A-1) as an example, the process for producing a solar cell module of the first embodiment will be described in detail with reference to the drawings.

### (Step (a))

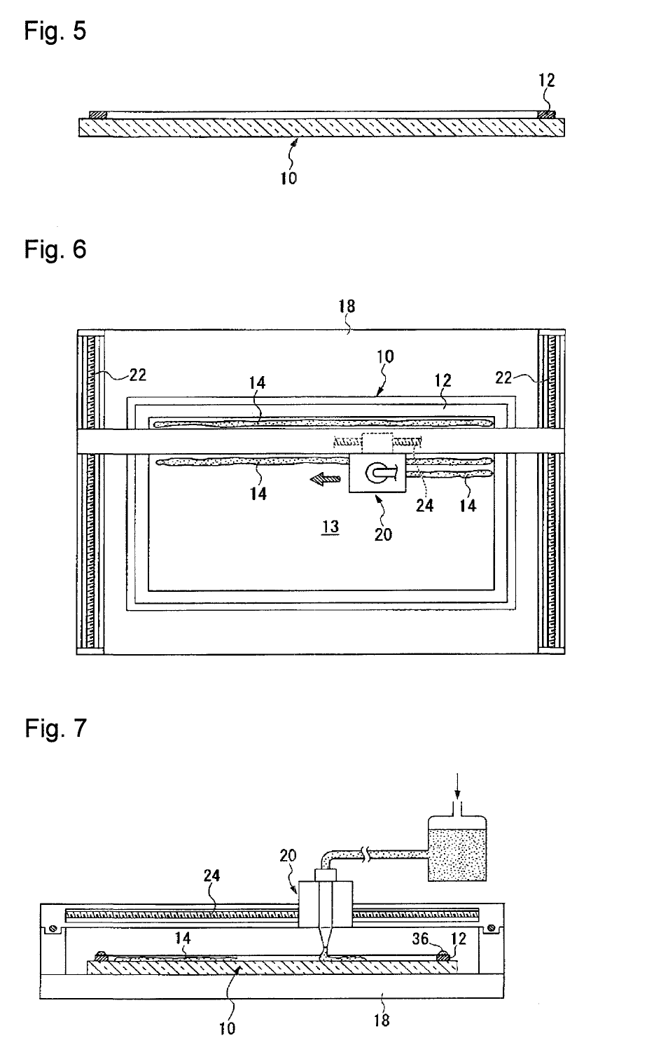

As shown in FIGS. 4 and 5, a double-sided adhesive tape 12 is bonded along the edge of a transparent surface material 10 (the first surface material) to form part of a seal part.

### (Step (b))

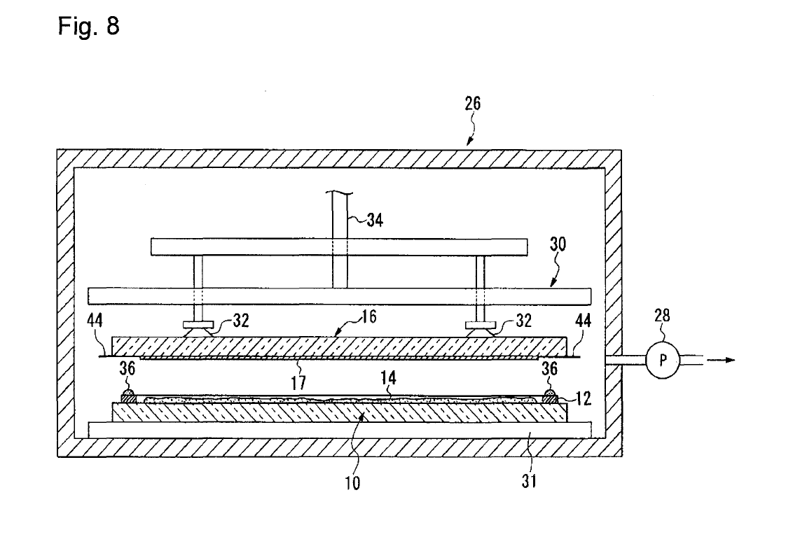

Then, as shown in FIGS. 6 and 7, a photocurable resin composition 14 is supplied to a rectangular region 13 enclosed by the double-sided adhesive tape 12 of the transparent surface material 10. The amount of the photocurable resin composition 14 to be supplied is preliminarily set to be such an amount that the space sealed by the double-sided adhesive tape 12, the transparent surface material 10 and the glass substrate 16 (FIG. 8) is filled with the photocurable resin composition 14.

As shown in FIGS. 6 and 7, the supplying of the photocurable resin composition 14 is carried out by placing the transparent surface material 10 flatly on a lower platen 18 and supplying the photocurable resin composition 14 in a line-, strip- or dot-form by a dispenser 20 moving in a horizontal direction.

The dispenser 20 is made to be horizontally movable over the entire range of the region 13 by a known horizontal movement mechanism comprising a pair of feed screws 22 and a feed screw 24 perpendicular to the feed screws 22. Here, instead of the dispenser 20, a die coater may be employed.

Further, as shown in FIG. 7, it is preferred to apply a photocurable resin composition 36 for forming a seal part, on the surface of the double-sided adhesive tape 12.

### Step (c))

Then, as shown in FIG. 8, the transparent surface material 10 and a glass substrate 16 (the second surface material) are introduced into a reduced pressure apparatus 26. At an upper portion in the reduced pressure apparatus 26, an upper platen 30 having a plurality of adsorption pads 32 is disposed, and at a lower portion, a lower platen 31 is provided. The upper platen 30 is made to be movable in a vertical direction by an air cylinder 34.

The glass substrate 16 is attached to the adsorption pads 32 with its surface having a thin-film type solar cell device 17 formed, facing downward. The transparent surface material 10 is fixed on the lower platen 31 with the side having the photocurable resin composition 14 supplied facing upward.

Then, the air in the reduced pressure apparatus 26 is suctioned by a vacuum pump 28. After the atmospheric pressure in the reduced pressure apparatus 26 reaches a reduced pressure atmosphere of e.g. from 15 to 40 Pa, the glass substrate 16 is lowered in a state adsorbed and held by the adsorption pads 32 of the upper platen 30, towards the transparent surface material 10 waiting below, by operating the air cylinder 34. And, the transparent surface material 10 and the glass substrate 16 are laminated via the double-sided adhesive tape 12 to form a laminate precursor, and the laminate precursor is held in a reduced pressure atmosphere for a prescribed period of time.

Here, the attaching position of the transparent surface material 10 to the lower platen 31, the number of adsorption pads 32, the attaching position of the glass substrate 16 to the upper platen 30, etc. are suitably adjusted depending upon the sizes, shapes, etc. of the transparent surface material 10 and the glass substrate 16. At that time, the glass substrate can be held in the reduced pressure atmosphere stably by using electrostatic chucks as the adsorption pads and adopting the electrostatic chuck holding method as disclosed in the specification of Japanese Patent Application No. 2008-206124.

### (Step (d))

Then, the interior of the reduced pressure apparatus 26 is made to be e.g. atmospheric pressure, whereupon the laminate precursor is taken out from the reduced pressure apparatus 26. When the laminated precursor is placed in the atmospheric pressure atmosphere, the surface on the transparent surface material 10 side and the surface of the glass substrate 16 side of the laminated precursor are pressed by the atmospheric pressure, and the photocurable resin composition 14 in the sealed space is pressed by the transparent surface material 10 and the glass substrate 16. By this pressure, the photocurable resin composition 14 in the sealed space will flow, and the entire sealed space will be uniformly filled with the photocurable resin composition 14. Thereafter, ultraviolet rays are applied from the transparent surface material 10 side of the laminate precursor, to cure the photocurable resin composition 14 in the interior of the laminate precursor thereby to obtain a solar cell module.

In the foregoing, the process for producing a solar cell module of the present invention has been described in detail by taking the case of the method (A-1) as an example. However, also in the case of other methods (A-2, B-1, B-2, C-1 and C-2), solar cell modules can be produced in the same manner.

In the case of the method (A-2), seal part is formed on the edge of the surface of the glass substrate on the side where a thin-film type solar cell device is formed, and a photocurable resin composition is supplied to the region enclosed by the seal part. Then, the glass substrate is introduced into a reduced pressure apparatus, and after the interior of the reduced pressure apparatus is made to be a prescribed reduced pressure atmosphere, a transparent surface material is laminated on the glass substrate to seal the photocurable resin composition, and the obtained laminate precursor is placed in an atmosphere under a pressure of not less than 50 kPa, and the photocurable resin composition is photo-cured to obtain a solar cell module.

In the case of the method (B-1), a seal part is formed on the surface of a glass substrate on the side where a solar cell device is formed, and a solar cell module is produced in the same manner as in the case of the method (A-2).

In the case of the method (B-2), a seal part is formed on the surface of a transparent surface material, and a solar cell module is produced in the same manner as in the case of the method (A-1).

### (Function Effects)

According to the above-described process for producing the present invention, it is possible to produce a solar cell module having a relatively large area without forming air bubbles in the resin layer. Even if air bubbles remain in the curable resin composition sealed under reduced pressure, in a high pressure atmosphere before the curing, the pressure is exerted also to the sealed curable resin composition to reduce the volume of the air bubbles, whereby the air bubbles will readily disappear. For example, the volume of a gas in air bubbles in the curable resin composition sealed under 100 Pa is considered to become 1/1000 under 100 kPa. The gas may be dissolved in the curable resin composition, and the gas in the air bubbles of a very small volume will readily be dissolved in the photocurable resin composition and thus disappear.

Further, even if a pressure such as an atmospheric air pressure is exerted to the curable resin composition after sealing, since the liquid state curable resin composition is a composition with fluidity, the pressure is uniformly distributed over the surface of the thin-film type solar cell device, whereby there will be no such a possibility that a higher stress is exerted to a part of the surface of the thin-film type solar cell device in contact with the curable resin composition, and there will be no substantial possibility of a damage of the thin-film type solar cell device. Further, in a case where the curable resin composition is a photocurable resin composition, a high temperature is not required for the curing, and therefore, there will be no substantial possibility of a damage of the thin-film type solar cell device by a high temperature.

Further, the interface bonding strength between the resin layer formed by curing of the curable resin composition and the thin-film type solar cell device or the surface material is higher than the interface bonding strength by fusion of a thermal fusion resin. Besides, the curable resin composition with fluidity is pressed to adhere to the surface of the thin-film type solar cell device or the surface material and cured in such a state, whereby a higher interface bonding strength can be obtained, and at the same time, uniform bonding to the surface of the thin-film type solar cell device or the surface material can be obtained, thus minimizing the possibility of partial lowering of the interface bonding strength. Therefore, there is little possibility of peeling at the surface of the resin layer, and there is little possibility of inclusion of moisture or a corrosive gas from a portion where the interface bonding strength is inadequate.

Furthermore, as compared with a method (injection method) of injecting a curable resin composition with fluidity to a space having a wide area and a narrow distance between a pair of surface materials, it is possible to fill the curable resin composition in a short period of time without no substantial formation of air bubbles. Besides, it is possible to easily fill a high viscosity curable resin composition with little restriction with respect to the viscosity of the curable resin composition. Therefore, it is possible to employ a curable resin composition with a high viscosity containing a relatively high molecular weight curable compound, whereby the strength of the resin layer can be improved.

### EXAMPLES

Now, Examples will be described which were carried out to confirm the effectiveness of the present invention. Examples 1 and 2 are Working Examples of the present invention, and Example 3 is a Comparative Example.

### Example 1

On a surface of soda lime glass having a length of 1,300 mm, a width of 1,100 mm and a thickness of 3.9 mm, a transparent electrode layer having a thickness of 0.7 μm and made of tin oxide having fluorine added, was formed by a CVD method. Then, such a transparent electrode layer was segmented into strip lines with a width of about 50 μm and with a pitch of 9 mm by means of a fundamental wave (1,064 nm) of YAG laser.

On the transparent electrode layer, using monosilane gas as the starting material, three layers of amorphous silicon film were formed in the order of p-film, i-film and n-film by a plasma CVD method to obtain a photoelectric conversion layer having a total thickness of about 0.5 μm. Then, such a photoelectric conversion layer was segmented into strip lines with a width of about 50 μm and with a pitch of 9 mm by means of a second harmonic (532 nm) of YAG laser.

On the patterned photoelectric conversion layer, a ZnO film having a thickness of about 0.2 μm was formed by a sputtering method, and further a silver film having a thickness of about 0.2 μm was formed to form a back surface electrode layer. Then, the back surface electrode layer and the photoelectric conversion layer were all at once segmented into strip lines with a width of about 50 μm and with a pitch of 9 μm by means of a second harmonic (532 nm) of YAG laser. The back surface electrode layer and the transparent electrode layer were subjected to terminal processing to prepare a glass substrate A having a thin-film type solar cell device using amorphous silicon as a semiconductor.

### (Step (a))

On the edge of soda lime glass (hereinafter referred to as glass plate B) having a length of 1,300 mm, a width of 1,100 mm and a thickness of 3 mm with the same size as the glass substrate A, a double-sided adhesive tape (seal member) having a thickness of 1 mm and a width of 10 mm was bonded, and a release film on the surface was peeled.

A polypropylene glycol having a number average molecular weight of about 2,000 as calculated from the hydroxy value and isophorone diisocyanate were mixed in a molar ratio of about 1:2 and reacted in the presence of a catalyst of a tin compound to obtain a prepolymer, to which 2-hydroxyethyl acrylate was added in a molar ratio of about 1:2 and reacted to obtain an urethane acrylate oligomer (hereinafter referred to as UA-1). Of UA-1, the number of functional groups was 2, the measured value of the number average molecular weight was about 6,000, and the measured value of the viscosity at 40° C. was about 10.5 Pa·s.

100 Parts by mass of UA-1 and 1 part by mass of benzoin isopropyl ether (photopolymerization initiator) were uniformly mixed to obtain a photocurable resin composition C for forming a seal part. The photocurable resin composition C was applied to the surface of the double-sided adhesive tape in an applied thickness of about 0.3 mm by a dispenser.

### (Step (b))

40 Parts by mass of UA-1, 40 parts by mass of 2-hydroxubutyl methacrylate (Lightester HOB, manufactured by Kyoeisha Chemical Co., Ltd.) and 20 parts by mass of n-octadecyl methacrylate were uniformly mixed, and to 100 parts by mass of such a mixture, 0.1 part by mass of bis(2,4,6-trimethylbenzoyl)-phenylphosphine oxide (IRGACURE 819, manufactured by Ciba Specialty Chemicals) as a photopolymerization initiator, 0.02 part by mass of 2,5-di-t-butylhydroquinone as a polymerization inhibitor, and 0.5 part by mass of 1,4-bis(3-mercaptbutylyloxy)butane (Karenz MT BD-1, manufactured by Showa Denko K.K.) as a chain transfer agent, were uniformly dissolved to obtain a photocurable resin composition D.

The photocurable resin composition D was, in an open state as put in a container, placed in a reduced pressure chamber, and the interior of the reduced pressure chamber was depressurized to about 20 Pa·s and maintained for 10 minutes to carry out defoaming treatment.

About 10 g of the photocurable resin composition D was put in a container (HT-2 DB-100, manufactured by Brookfield) for measuring a viscosity and placed in a temperature-maintaining apparatus for measuring a viscosity, and the temperature of the photocurable resin composition was adjusted to be 25° C. Then, a spindle for measurement (SC4-31, manufactured by Brookfield) attached to a viscometer (LVDV-II+pro manufactured by Brookfield) was dipped into the photocurable resin composition in the measurement container, and while rotating the spindle at a speed of 0.3 rpm, held for 15 minutes, whereupon the viscosity of the photocurable resin composition D was measured and found to be 0.16 Pa·s.

To a region enclosed by the double-sided adhesive tape on the surface of the glass plate B, the photocurable resin composition D was supplied at plural positions by means of a dispenser so that the total mass would be 1,500 g.

### (Step (c))

On the upper surface of a lower platen in a vacuum chamber wherein a lifting and lowering apparatus comprising a pair of platens is set, the glass plate B was flatly placed so that the surface of the curable resin composition faced upward.

The glass substrate A was held on the lower surface of an upper platen of the lifting and lowering apparatus in the vacuum chamber by means of an electrostatic chuck so that the surface on the side where a thin-film type solar cell device was formed, faced the glass plate B and so that as viewed from above, it would be at the same position as the glass plate B, and in the vertical direction, the distance from the glass plate B would be 30 mm.

The vacuum chamber was made in a sealed state and evacuated until the pressure in the chamber became about 15 Pa. By the lifting and lowering apparatus in the vacuum chamber, the upper and lower platens were brought to be closer to each other so that the glass substrate A and the glass plate B were pressed under a pressure of 2 kPa via the photocurable resin composition D and held for 1 minute. The electrostatic chuck was deactivated, and from the upper platen, the glass substrate A was released, and the interior of the vacuum chamber was returned to the atmospheric pressure in about 60 seconds to obtain a laminate precursor E having the photocurable resin composition D sealed by the glass substrate A, the glass plate B and the seal part.

### (Step (d))

To the photocurable resin composition C applied to the surface of the double-sided adhesive tape on the edge of the laminate precursor E, ultraviolet rays were applied from a fiber light source using a high pressure mercury lamp as the light source, via the glass plate B, to cure the photocurable resin composition C, and the laminated precursor E was held horizontally to stand still for about 1 hour.

By applying ultraviolet rays from the high pressure mercury lamp uniformly from the surface direction of the laminate precursor E, the photocurable resin composition D was cured thereby to obtain a solar cell module F. The solar cell module F was a good one with a high transparency such that the haze value was not more than 1% at the portion free from the thin-film type solar cell device, and no defects such as air bubbles remaining in the resin layer were observed even though a step of removing air bubbles required during the production by a conventional injection method, was not required. Here, the haze value was a value obtained by the measurement in accordance with ASTM D1003 using a haze guard II manufactured by Toyo Seiki Seisaku-sho, Ltd.

The solar cell module F was exposed to sunlight during the daytime, whereby the electric power between the terminals was measured, and the output was 55 W.

### Example 2

A bi-functional polypropylene glycol having molecular terminals modified by ethylene oxide (number average molecular weight calculated from the hydroxy value: 4,000) and isophorone diisocyanate were mixed in a molar ratio of 3:4 and reacted in the presence of a catalyst of a tin compound to obtain a prepolymer, to which 2-hydroxyethyl acrylate was added in a molar ratio of about 1:2 and reacted to obtain an urethane acrylate oligomer (hereinafter referred to as UA-2). Of UA-2, the number of curable groups was 2, the number average molecular weight was about 21,000, and the viscosity at 40° C. was 93 Pa·s.

40 Parts by mass of UA-2, 40 parts by mass of 2-hydroxubutyl methacrylate (Lightester HOB, manufactured by Kyoeisha Chemical Co., Ltd.) and 20 parts by mass of n-dodecyl methacrylate were uniformly mixed, and to 100 parts by mass of such a mixture, 0.2 part by mass of bis(2,4,6-trimethylbenzoyl)-phenylphosphine oxide (photopolymerization initiator, IRGACURE 819, manufactured by Ciba Specialty Chemicals), 0.04 part by mass of 2,5-di-t-butylhydroquinone (polymerization inhibitor), and 0.3 part by mass of an ultraviolet absorber (TINUVIN 109, manufactured by Ciba Specialty Chemicals) were uniformed dissolved to obtain a photocurable resin composition G. The above photocurable resin composition G was, in an open state as contained in a container, placed in a reduced pressure apparatus, and the interior of the reduced pressure apparatus was depressurized to about 20 Pa and maintained for 10 minutes to carry out defoaming treatment. The viscosity at 25° C. of the photocurable resin composition G was measured and found to be 1.1 Pa·s.

A laminate precursor H having the photocurable resin composition G sealed by the glass substrate A, the glass plate B and the seal part, was obtained in Step (c) in the same manner as in Example 1 except that the above photocurable resin composition G was used instead of the photocurable resin composition D of Step (b).

The laminate precursor H was held horizontally to stand still for about 10 minutes, and then light was irradiated uniformly from the surface direction of the laminate precursor H from chemical lamps arranged in parallel to cure the photocurable resin composition G thereby to obtain a solar cell module I. The solar cell module I was a good one with high transparency such that also the haze was not more than 1% at the portion free from the thin-film type solar cell device, and no defects such as air bubbles remaining in the resin layer were observed.

The solar cell module I was exposed to sunlight during the daytime, whereby the electric power between the terminals was measured, and the output was 52 W.

### Example 3

A double-sided adhesive tape having a thickness of 1 mm and a width of 10 mm was bonded to the edge of the glass plate B, and while leaving the release film of the double-sided adhesive tape only along one side, the release film on the surface was peeled. On the glass plate B, the glass plate A was laminated and bonded by the double-sided adhesive tape along the three sides.

On one side where the release film was left, and space between the double-sided adhesive tape and the glass substrate A was forced open for about 2 mm by a screw driver, and it was attempted to inject 1,500 g of the photocurable resin composition from the opened space, but air bubbles remained at a lower portion of the space between the glass substrate A and the glass plate B, and it was not possible to densely inject the photocurable resin composition D into the space.

### INDUSTRIAL APPLICABILITY

According to the process for producing a solar cell module of the present invention, a thin-film type solar cell device to be sealed is less susceptible to breakage, the interface bonding strength between the resin layer and the thin-film type solar cell device and the interface bonding strength between the resin layer and the surface materials can be made high, and formation of air bubbles by the liquid state curable resin composition can sufficiently be suppressed, and therefore, such a process is useful for the production of a solar cell module with high quality and high durability.

This application is a continuation of PCT Application No. PCT/JP2010/059637, filed Jun. 7, 2010, which is based upon and claims the benefit of priority from Japanese Patent Application No. 2009-139426 filed on Jun. 10, 2009. The contents of those applications are incorporated herein by reference in its entirety.

### REFERENCE SYMBOLS

1: Solar cell module
2: Solar cell module
3: Solar cell module
10: Transparent surface material (first surface material)
12: Double-sided adhesive tape
14: Photocurable resin composition
16: Glass substrate (second surface material)
17: Thin-film type solar cell device
36: Photocurable resin composition
40: Resin layer
42: Seal part

What is claimed is:

1. A process for producing a solar cell module comprising first and second surface materials, at least one of which has optical transparency, a resin layer interposed between the first and second surface materials, a thin-film type solar cell device formed on the surface, on the resin layer side, of at least one of the first and second surface materials, and a seal part enclosing the periphery of the resin layer, which process comprises the following steps (a) to (d):
(a) a step of forming a seal part on the edge of a surface of a first surface material (provided that in a case where a thin-film type solar cell device is formed on a surface of the first surface material, the seal part is formed on the edge of the surface on the side where the thin-film solar cell device is formed),
(b) a step of supplying a liquid state curable resin composition to the region enclosed by the seal part of the first surface material,
(c) a step of laminating, in a reduced pressure atmosphere of not more than 100 Pa, a second surface material on the first surface material so as to be in contact with the curable resin composition formed on the first surface material thereby to obtain a laminated material having the curable resin composition hermetically sealed by the first and second surface materials and the seal part (provided that in a case where a thin-film type solar cell device is formed on a surface of the second surface material, the second surface material is laminated so that the surface on the side where the thin-film type solar cell device is formed, is in contact with the curable resin composition formed on the first surface material), and
(d) a step of curing the curable resin composition in such a state that the laminated material is placed in a pressure atmosphere of not less than 50 kPa to form a resin layer.

2. The process according to claim 1, wherein one of the first and second surface materials is a glass substrate having a thin-film type solar cell device formed on its surface, and the other is a transparent surface material.

3. The process according to claim 2, wherein the transparent surface material is a glass plate.

4. The process according to claim 1, wherein the pressure atmosphere of not less than 50 kPa is an atmospheric pressure atmosphere.

5. The process according to claim 1, wherein the curable resin composition is a photocurable resin composition.

6. The process according to claim 5, wherein the photocurable resin composition comprises at least one compound having, per molecule, from 1 to 3 groups selected from the group consisting of acryloyloxy groups and methacryloyloxy groups, and a photo-polymerization initiator.

7. The process according to claim 1, wherein the thin-film type solar cell device is a thin-film silicon solar cell device.
